(19) United States
(12) Patent Application Publication
(10) Pub. No.: US 2023/0241646 A1
(43) Pub. Date: Aug. 3, 2023

(54) METHOD OF MANUFACTURING PIEZOELECTRIC ELEMENT ARRAY BOARD, PIEZOELECTRIC ELEMENT ARRAY BOARD, AND POLING APPARATUS

(71) Applicant: Shanghai Tianma Micro-Electronics Co., Ltd., Shanghai (CN)

(72) Inventors: Kenji SERA, Kawasaki (JP); Kenichi HAYASHI, Kawasaki (JP); Hiroshi HAGA, Kawasaki (JP); Shin TAKEUCHI, Kawasaki (JP)

(73) Assignee: Shanghai Tianma Micro-Electronics Co., Ltd., Shanghai (CN)

(21) Appl. No.: 18/157,319

(22) Filed: Jan. 20, 2023

(30) Foreign Application Priority Data
Jan. 31, 2022 (JP) 2022-012710

(51) Int. Cl. B06B 1/06; H10N 30/045

(52) U.S. Cl. CPC B06B 1/0692; H10N 30/045

(57) ABSTRACT

A method of manufacturing a piezoelectric element array board includes fabricating a plurality of piezoelectric element control circuits including one or more thin-film transistors on a substrate, fabricating a plurality of piezoelectric elements on the substrate, and poling a piezoelectric material by applying an electric field to a piezoelectric material layer of the plurality of piezoelectric elements while maintaining the one or more thin-film transistors in a state of generating higher leakage current, after fabricating the plurality of piezoelectric elements and the plurality of piezoelectric element control circuits.

### CROSS-REFERENCE TO RELATED APPLICATIONS

This non-provisional application claims priority under 35 U.S.C. § 119(a) on Patent Application No. 2022-012710 filed in Japan on Jan. 31, 2022, the entire content of which is hereby incorporated by reference.

### BACKGROUND

This disclosure relates to a method of manufacturing a piezoelectric element array board, a piezoelectric element array board, and a poling apparatus.

A piezoelectric element array is included in various devices such as an ultrasonic sensor, an ultrasonic transducer array, and a fingerprint sensor. Recently, an active-matrix ultrasonic fingerprint sensor has been commercialized that includes arrayed piezoelectric elements and thin-film transistor (TFT) pixel circuits for driving and controlling the piezoelectric elements.

The ultrasonic fingerprint sensor is configured in such a manner that thin-film piezoelectric elements are fabricated above a low-temperature polysilicon (LTPS) TFT array, which is included in an LCD, for example. Manufacturing the ultrasonic fingerprint sensor first fabricates a TFT array by normal LTPS processes and thereafter, fabricates piezoelectric elements. Lastly, high-voltage treatment (poling) at approximately 1000 V is necessary for the piezoelectric elements to exhibit piezoelectricity.

### SUMMARY

An aspect of this disclosure is a method of manufacturing a piezoelectric element array board. The method includes: fabricating a plurality of piezoelectric element control circuits including one or more thin-film transistors on a substrate; fabricating a plurality of piezoelectric elements on the substrate; and poling a piezoelectric material by applying an electric field to a piezoelectric material layer of the plurality of piezoelectric elements while maintaining the one or more thin-film transistors in a state of generating higher leakage current, after fabricating the plurality of piezoelectric elements and the plurality of piezoelectric element control circuits.

An aspect of this disclosure is a piezoelectric element array board, including: a substrate; a piezoelectric element array including a plurality of piezoelectric elements on the substrate; and a thin-film transistor array on the substrate, the thin-film transistor array being configured to control the plurality of piezoelectric elements. The thin-film transistor array includes a plurality of piezoelectric element control circuits each configured to control one of the plurality of piezoelectric elements. Leakage current of each of the one or more thin-film transistors at 80° C. is equal to or higher than a value obtained by multiplying an area of a piezoelectric element by 0.1 A.

An aspect of this disclosure is a poling apparatus configured to pole a piezoelectric material in a piezoelectric element array board. The piezoelectric element array board includes an insulating substrate, a plurality of piezoelectric element control circuits including one or more thin-film transistors on the insulating substrate, and a plurality of piezoelectric elements including a piezoelectric material layer on the insulating substrate.

The poling apparatus includes: a plasma discharging device; an optically transparent stage configured to hold the piezoelectric element array board placed in such a manner that the insulating substrate is on the optically transparent stage; a heating device configured to heat the piezoelectric element array board; and a light source system configured to irradiate the piezoelectric element array board with light from behind the optically transparent stage. The plasma discharging device is configured to pole the piezoelectric material layer of the plurality of piezoelectric elements by electrifying the piezoelectric element array board in a state where the piezoelectric element array board is heated and being irradiated with light.

It is to be understood that both the foregoing general description and the following detailed description are exemplary and explanatory and are not restrictive of this disclosure.

### BRIEF DESCRIPTION OF THE DRAWINGS

FIG. 1 is a block diagram illustrating a configuration of an ultrasonic sensor in an embodiment;

FIG. 2 is a circuit diagram illustrating a circuit configuration of a pixel of a piezoelectric element array board in an embodiment;

FIG. 3 is a timing chart illustrating operation of an ultrasonic sensor of this disclosure to excite ultrasonic waves and further to receive reflected ultrasonic waves;

FIG. 4 schematically illustrates a part of the cross-sectional structure of an ultrasonic sensor;

FIG. 5 is a flowchart of an example of a method of manufacturing an ultrasonic sensor;

FIG. 6 schematically illustrates a configuration of a pixel circuit in a poling process;

FIG. 7 illustrates relations between the gate voltage and the drain current of a p-channel type of thin-film transistor at different temperatures;

FIG. 8 provides measured hysteresis loops (D-E hysteresis loops) representing relations between the electric field E applied to a piezoelectric element at different temperatures and the charge density D;

FIG. 9 illustrates a relation between the coercive electric field Ec and the temperature and a relation between the remanent polarization Pr and the temperature of a piezoelectric element;

FIG. 10 schematically illustrates a poling process while irradiating the piezoelectric element array board with light;

FIG. 11 illustrates a relation between the off-current of a thin-film transistor in a piezoelectric element array board and the breakdown electric field for the thin-film transistor; and

FIG. 12 schematically illustrates a configuration example of an apparatus for poling a piezoelectric material layer while irradiating the piezoelectric element array board with light.

### EMBODIMENTS

Hereinafter, an ultrasonic sensor of this disclosure will be described in detail with reference to drawings. The elements in each drawing are changed in size or scale as appropriate to be well recognized in the drawing. The hatches in the drawings are to distinguish the elements and are not to represent cross-sections. The non-linear elements used as switching elements or amplifying elements are referred to as transistors. The transistors include thin-film transistors (TFTs).

The piezoelectric element array board of this disclosure is applicable to ultrasonic sensors in the fields of medical and industrial testing and ultrasonic sensors for detecting a fingerprint or an object. It is further applicable to sound generators to be used for various purposes. Although the currently commercialized ultrasonic sensors are configured with an array of a plurality of isolated piezoelectric elements, active-matrix ultrasonic sensors to be driven by an array of thin-film transistors have been launched to the market to achieve a thinner shape and higher resolution.

Manufacturing a piezoelectric element includes a process of poling a piezoelectric material by applying an electric field higher than the coercive electric field to the piezoelectric material. Specifically, a high electric field of approximately 100 V/μm (active voltage of 1000 V) is generally required to attain piezoelectricity. In the meanwhile, in a piezoelectric element array board to be driven and controlled by a TFT array, each piezoelectric element is connected to thin-film transistors. To detect and read a signal from a piezoelectric element, the thin-film transistors are demanded to have small off-current. However, if the leakage current of a thin-film transistor is small, the voltage applied to the thin-film transistor during the poling process becomes high, the thin-film transistor will be broken with high probability.

An embodiment of this specification configures and manufactures a piezoelectric element array board so that the thin-film transistors have desirable leakage current during the poling process of the piezoelectric elements. As a result, the possibility of breakage of thin-film transistors in manufacturing a piezoelectric element array board significantly decreases.

### Device Configuration

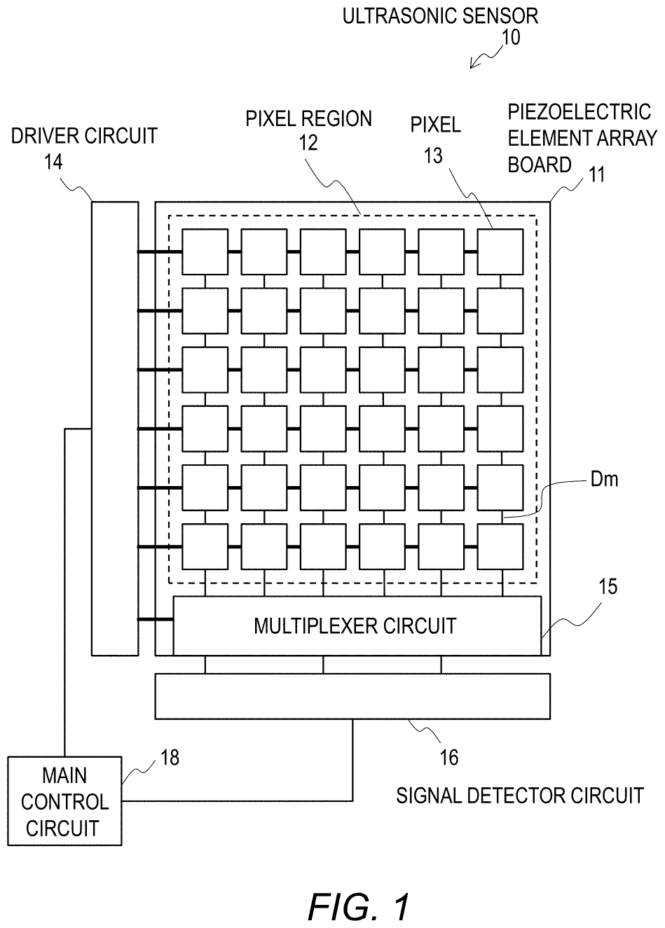

FIG. 1 is a block diagram illustrating a configuration example of an ultrasonic sensor in an embodiment of this specification. The ultrasonic sensor 10 includes a piezoelectric element array board 11 and control circuits. The control circuits include a multiplexer circuit 15, a driver circuit 14, a signal detector circuit 16, and a main control circuit 18.

The piezoelectric element array board 11 includes an insulating substrate (such as a glass substrate) and a pixel region 12 in which pixels 13 are arrayed horizontally and vertically like a matrix on the insulating substrate. The multiplexer circuit 15 is fabricated on the insulating substrate of the piezoelectric element array board 11 and connected to signal lines of pixel columns each consisting of pixels aligned vertically in FIG. 1. The multiplexer circuit 15 converts signals from the pixels in time series and outputs the converted signals to a smaller number of signal lines connected to the signal detector circuit 16 for detection.

The driver circuit 14 drives and controls the pixels 13 for the pixels 13 to generate and detect ultrasonic waves. The multiplexer circuit 15 receives an ultrasonic detection signal from a pixel 13 transmitted by a signal line and outputs it to the signal detector circuit 16. The signal detector circuit 16 detects signals from individual signal lines converted in time series by the multiplexer circuit 15. The main control circuit 18 controls the driver circuit 14, the multiplexer circuit 15, and the signal detector circuit 16. The driver circuit 14, the signal detector circuit 16, and the main control circuit 18 can be mounted on the piezoelectric element array board 11 or separately from the piezoelectric element array board 11 as independent components.

### Pixel Circuit

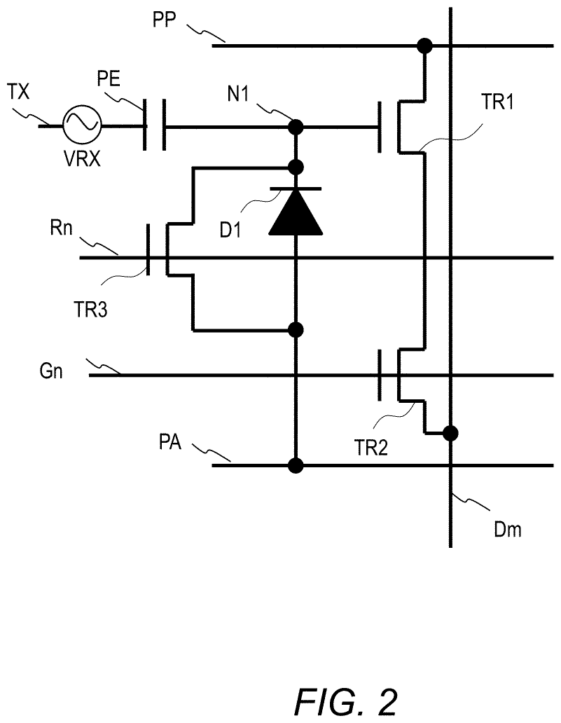

FIG. 2 is a circuit diagram illustrating the configuration of a pixel 13 and a pixel circuit (piezoelectric element control circuit) for the pixel 13. The pixel 13 is a piezoelectric element PE. This piezoelectric element PE has two functions to excite and receive ultrasonic waves. An upper electrode of the piezoelectric element PE is denoted by a reference sign TX. The piezoelectric element PE induces a voltage VRX in accordance with received reflected ultrasonic vibration. One pixel circuit in the ultrasonic sensor 10 of this disclosure includes three thin-film transistors TR1, TR2, and TR3, and a diode D1. The semiconductor material of the thin-film transistors can be low-temperature polysilicon, an oxide semiconductor, or amorphous silicon.

The cathode terminal of the diode D1 is connected to a node N1 between the gate terminal of the transistor TR1 and a source/drain terminal of the transistor TR3. The anode terminal is connected to a diode bias line PA. One of the source/drain terminals of the transistor TR1 is connected to a power line PP and the other source/drain terminal is connected to one of the source/drain terminals of the transistor TR2.

The gate terminal of the transistor TR2 is connected to a control line Gn. The other source/drain terminal of the transistor TR2 is connected to a signal line Dm. The gate terminal of the transistor TR3 is connected to a control line Rn. The source/drain terminals of the transistor TR3 are connected to the anode terminal and the cathode terminal of the diode D1.

The transistor TR1 (amplifier transistor) has a function to amplify the potential at one end of the piezoelectric element PE. The transistor TR2 is a switching element and has a function to control the output of the pixel circuit. The transistor TR3 is a switching element and has a function to reset the potentials of one end of the piezoelectric element PE and the gate electrode of the transistor TR1.

The ultrasonic sensor 10 in FIG. 1 has one signal line Dm for one pixel column consisting of a plurality of vertically aligned pixels 13. All pixels in the same pixel column are connected to the signal line Dm. This signal line Dm is connected to one multiplexer circuit 15 in an end region of the piezoelectric element array board 11.

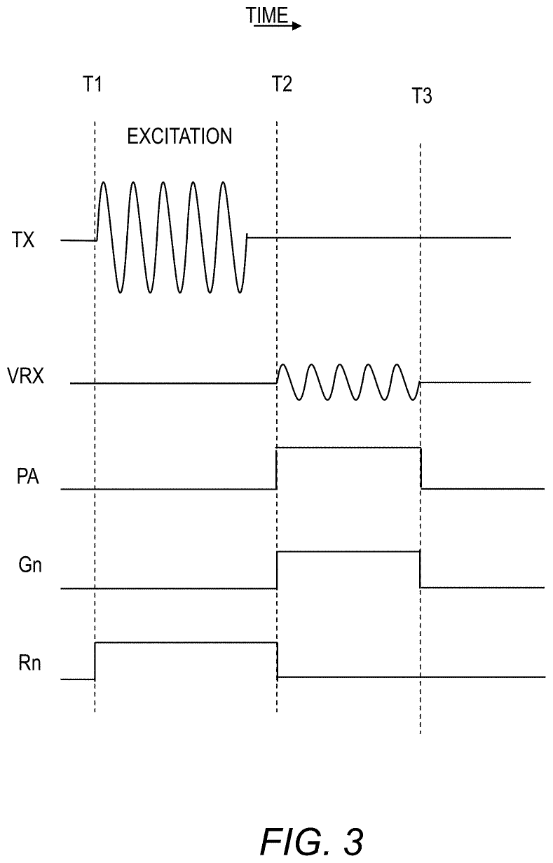

FIG. 3 is a timing chart illustrating operation of the ultrasonic sensor 10 of this disclosure to excite ultrasonic waves and further, to receive reflected ultrasonic waves. The period from a time T1 to a time T2 is an ultrasonic wave excitation period.

At the time T1, the driver circuit 14 changes the potential of the control line Rn from a Low level to a High level. In response, the transistor TR3 turns ON. The driver circuit 14 maintains the potential of the diode bias line PA at a Low level. As a result, the potential of the lower electrode of the piezoelectric element PE is fixed. After turning ON the transistor TR3, the driver circuit 14 supplies an excitation signal to the upper electrode TX of the piezoelectric element PE. In response, all piezoelectric elements PE start vibrating to generate ultrasonic waves. Subsequently, the driver circuit 14 stops supplying the signal to the upper electrode TX.

At the time T2 after stopping the signal for the upper electrode TX, the driver circuit 14 changes the potential of the control line Rn from a High level to a Low level. In response, the transistor TR3 turns OFF.

The piezoelectric element PE receives reflected ultrasonic waves from the time T2. Since the transistor TR3 is OFF, the lower electrode is in a floating state, so that an inductive voltage VRX is generated at the lower electrode in response to receipt of ultrasonic waves. In FIG. 3, if the piezoelectric element PE is not receiving ultrasonic waves, the inductive voltage VRX is 0 and if receiving, the inductive voltage VRX is higher than 0.

The driver circuit 14 further changes the potential of the diode bias line PA from a Low level to a High level at the time T2. Diode biasing adjusts the inductive voltage VRX to an optimum bias voltage for the transistor TR1 to output to the signal line Dm.

The driver circuit 14 further changes the potential of the control line Gn from a Low level to a High level at the time T2. In response, the transistor TR2 turns ON; the transistor TR1 amplifies the inductive voltage VRX and outputs it to the signal line Dm.

At a time T3, the driver circuit 14 changes the potential of the control line Gn from a High level to a Low level. In response, the transistor TR2 turns OFF, so that reading the inductive voltage VRX ends. This timing chart illustrates operation of only one pixel. In the case where the device has a plurality of pixels, the driver circuit 14 controls a plurality of control lines Rn and Gn, and a plurality of signal lines Dm to read the inductive voltage VRX of each pixel.

### Element Structure

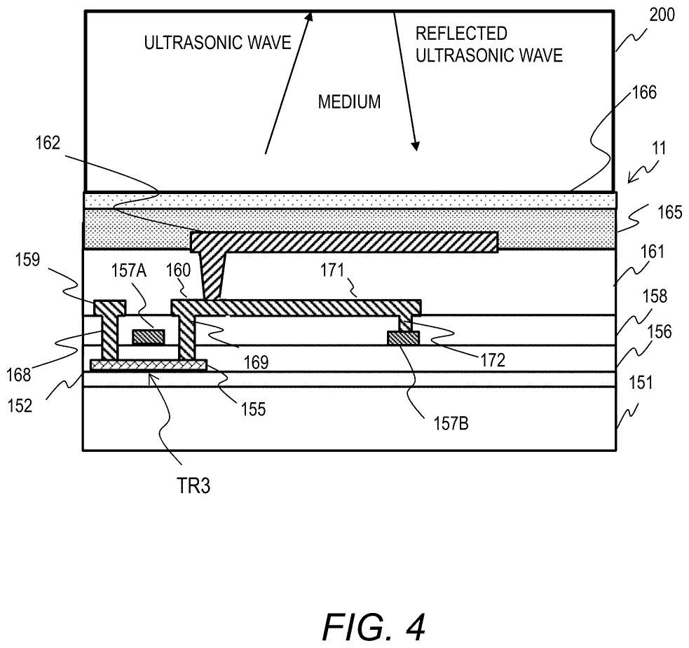

FIG. 4 schematically illustrates a part of the cross-sectional structure of the ultrasonic sensor 10. The definitions of top and bottom in the following description correspond to the top and the bottom of the drawings. The ultrasonic sensor 10 includes an insulating substrate 151 and a medium 200 opposed to the insulating substrate 151. The medium 200 is a flexible or rigid insulating substrate made of resin or glass, for example. Not only a uniform insulator but also a flat-panel display substrate that does not affect ultrasonic waves can be employed. The ultrasonic waves generated by the ultrasonic sensor 10 are reflected off the surface of the medium 200 opposite to the ultrasonic sensor 10 and returns to the ultrasonic sensor 10. If an object such as a human skin is in contact with the surface of the medium 200, the reflection rate of the ultrasonic waves changes. Whether a human skin is present can be sensed with the intensity of the reflected ultrasonic waves.

The ultrasonic sensor 10 includes a plurality of lower electrodes 162, one upper electrode 166, and a piezoelectric material layer 165 on the insulating substrate 151. The piezoelectric material can be either organic or inorganic; for example, polyvinylidene fluoride (PVDF) or zirconate titanate (PZT) can be employed.

One lower electrode 162, a part of the upper electrode 166, and a part of the piezoelectric material layer 165 constitute one piezoelectric element (also referred to as pixel). The upper electrode and the piezoelectric material layer can be separated for each piezoelectric element. One piezoelectric material layer 165 is disposed between the upper electrode 166 and the lower electrodes 162. The plurality of lower electrodes 162 are provided on a planarization film 161 and the piezoelectric material layer 165 is provided over the lower electrodes 162.

The ultrasonic sensor 10 includes a plurality of circuits each including a plurality of switches. Each circuit drives and controls a piezoelectric element and it can be referred to as pixel circuit. The pixel circuits are fabricated between the insulating substrate 151 and the lower electrodes 162 and control the potentials to be supplied to individual lower electrodes 162. The configuration example illustrated in FIG. 2 includes an upper electrode 166 common to a plurality of piezoelectric elements on the side to generate ultrasonic waves and receive reflected waves (the upper side of FIG. 4). The upper electrode 166 is shaped to fully cover the whole pixel region 12. The positions of the layer of the piezoelectric elements and the layer of the circuits can be reversed.

The pixel circuit in FIG. 4 includes a transistor TR3 and the gate electrode 1576 of a transistor TR1. The insulating substrate 151 is a rigid or flexible substrate made of glass or resin, for example. In the following description, the side closer to the insulating substrate 151 is referred to as lower side, the side farther from the insulating substrate 151 as upper side. A base insulating layer 152 made of an insulator is provided above the insulating substrate 151 and a semiconductor active layer 155 is laid above the base insulating layer 152. The semiconductor active layer 155 includes low-resistive source/drain regions and a highly resistive channel region sandwiched by the source/drain regions.

The semiconductor active layer 155 is covered with a gate insulating layer 156. Gate electrodes are provided above the semiconductor active layer 155 across the gate insulating layer 156. FIG. 4 includes the gate electrode 157A of the transistor TR3 and the gate electrode 1576 of the transistor TR1. An interlayer insulating film 158 is provided over the layer including the gate electrodes 157A and 1576.

Source/drain electrodes 159 and 160 are provided above the interlayer insulating film 158 within the pixel region 12. The source/drain electrodes 159 and 160 can be made of an aluminum-based alloy for example. The source/drain electrodes 159 and 160 are connected to the semiconductor active layer 155 through contact regions 168 and 169 provided in contact holes of the interlayer insulating film 158.

A line region 171 extends from the source/drain electrode 160 of the transistor TR3 and connects to the gate electrode 1576 of the transistor TR1 via a contact region 172 provided in a contact hole of the interlayer insulating film 158. The line region 171 and the source/drain electrode 160 are included in the same metal layer and they are unseparated.

An insulating planarization film 161 is provided over the source/drain electrodes 159 and 160, and the line region 171. A lower electrode 162 is provided above the insulating planarization film 161. The lower electrode 162 is connected to the source/drain electrode 160 via a contact region provided in a contact hole of the planarization film 161. The pixel circuit is fabricated below the lower electrode 162.

A piezoelectric material layer 165 is formed over the lower electrode 162. The piezoelectric material layer 165 is in contact with the top face of the lower electrode 162 and the top face of the planarization film 161. An upper electrode 166 is provided above and in contact with the piezoelectric material layer 165. The stack of the lower electrode 162, a part of the piezoelectric material layer 165, and a part of the upper electrode 166 corresponds to a piezoelectric element.

### Manufacturing Method

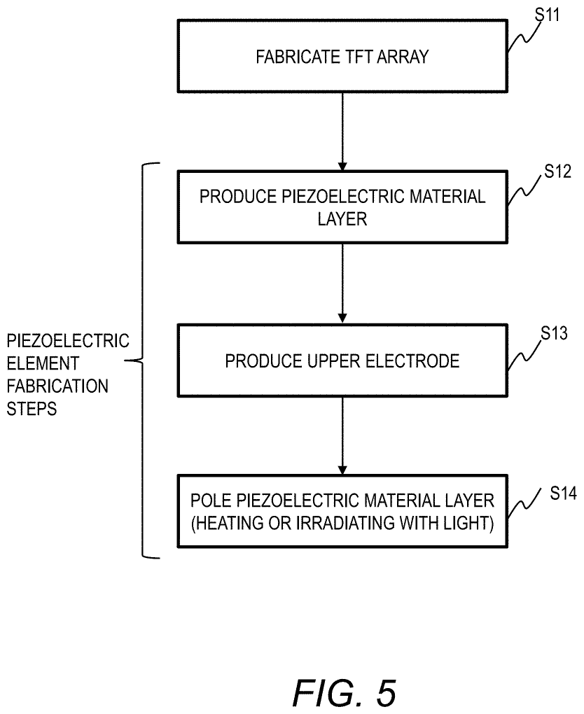

An example of a method of manufacturing an ultrasonic sensor 10 is described. In the following description, the elements produced in one step (simultaneously) are elements on the same layer. FIG. 5 is a flowchart of an example of a method of manufacturing an ultrasonic sensor 10.

Manufacturing an ultrasonic sensor 10 first fabricates a TFT array on an insulating substrate 151 (S11). The step is described specifically. The manufacturing first deposits silicon nitride or silicon oxide on an insulating substrate 151 by chemical vapor deposition (CVD) to form a base insulating layer 152.

Next, the manufacturing produces a layer (polysilicon layer) including a semiconductor active layer 155 by a known low-temperature polysilicon TFT manufacturing technique. For example, the manufacturing deposits amorphous silicon by CVD and crystalizes the amorphous silicon by excimer laser annealing (ELA) to form a polysilicon layer.

Next, the manufacturing deposits silicon oxide on the polysilicon layer including the semiconductor active layer 155 by CVD to form a gate insulating layer 156. Further, the manufacturing deposits metal material by sputtering and patterns the metal material to form a metal layer including gate electrodes 157A and 157B.

The metal layer can include not only the gate electrodes 157A and 157B but also lines. The metal layer can be a single layer of one material selected from a group consisting of Mo, W, Nb, MoW, MoNb, Al, Nd, Ti, Cu, a Cu alloy, An AL alloy, Ag, and an Ag alloy. Alternatively, the metal layer can have a multi-layered structure including two or more layers of low-resistive materials selected from Mo, Cu, Al, and Ag to attain low-resistive lines.

Next, to produce n-type TFTs, the manufacturing dopes the semiconductor active layer 155 in the regions already doped with n-type high-concentration impurities before forming the gate electrodes 157A and 157B with additional impurities using the gate electrodes 157A as a mask to form a low-concentration impurity layer. As a result, the TFTs are provided with a lightly-doped drain structure (LDD). Next, the manufacturing dopes the semiconductor active layer 155 in the regions other than the regions of the n-type TFTs with p-type impurities using the gate electrodes 157A as a mask to produce source/drain structures of p-type TFTs. Next, the manufacturing deposits silicon oxide by CVD to form an interlayer insulating film 158.

The manufacturing opens contact holes in the interlayer insulating film 158 and the gate insulating layer 156 by anisotropic etching. The contact holes for contact regions 168 and 169 for connecting source/drain electrodes 159 and 160 to the semiconductor active layer 155 and contact holes for contact regions 172 for connecting a line region 171 to a gate electrode 157B are opened in the interlayer insulating film 158 and the gate insulating layer 156.

Next, the manufacturing deposits metal materials containing aluminum such as Ti/Al/Ti and patterns the metal materials to form a metal layer. The metal layer includes source/drain electrodes 159 and 160, line regions 171, and contact regions 168, 169, and 172. Other lines are formed together.

Next, the manufacturing deposits a photosensitive organic material to form a planarization film 161 and opens contact holes to reach the source/drain electrodes 160 of the TFTs. The manufacturing produces lower electrodes 162 on the planarization film 161 having the contact holes. A lower electrode 162 can be a single layer of a material such as ITO, IZO, ZnO, Ag, Mg, Al, or Pt or a stack of such layers. Each lower electrode 162 is connected to a source/drain electrode 160 via a contact region.

After a TFT array is fabricated as described above, the manufacturing performs piezoelectric element fabrication steps S12 to S14. Specifically, the manufacturing produces a piezoelectric material layer (S12). An example of the producing a piezoelectric material layer deposits PVDF by spin coating, printing, or ink jet printing to form a piezoelectric material layer 165. A piezoelectric material different from PVDF can be deposited into a layer by an appropriate method.

Next, the manufacturing produces an upper electrode above the piezoelectric material layer 165 (S13). The producing the upper electrode deposits a metal material for the upper electrode 166 above the piezoelectric material layer 165. An example of forming the layer for the upper electrode 166 deposits Al and/or Ag by sputtering, vapor deposition, printing, or ink jet printing. The piezoelectric material layer 165 and the upper electrode 166 cover the whole pixel region 12 not to affect lines provided outside the pixel region 12.

Next, the manufacturing poles the piezoelectric material layer 165 formed on the substrate (S14). The poling process S14 applies a high voltage to the piezoelectric material layer 165 to develop the piezoelectricity of the piezoelectric material layer 165. To attain a desired level of piezoelectricity, a high electric field (high voltage) of approximately 100 V/μm (an actual voltage of approximately 1000 V) is to be applied.

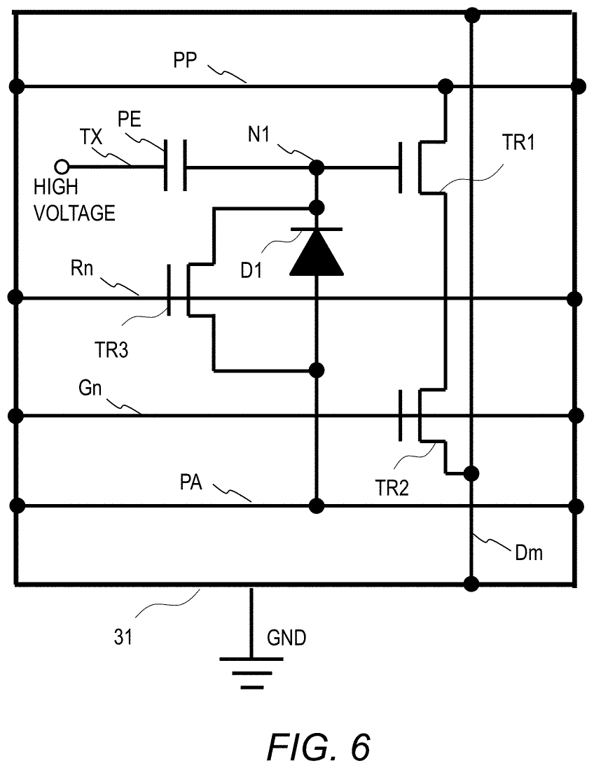

FIG. 6 schematically illustrates a configuration of a pixel circuit in the poling process. All lines of the thin-film transistor array (pixel circuit array) are connected to a common line 31 and grounded. Specifically, the power line PP, the control lines Rn and Gn, the diode bias line PA, and the signal line Dm are grounded. The poling process applies a high voltage to the upper electrode TX in the state where the lines of the thin-film transistor array are grounded to pole the piezoelectric material layer 165.

In general, manufacturing a piezoelectric element array board fabricates pixel arrays and thin-film transistor arrays for a plurality of piezoelectric element array boards on one mother board and cuts out individual piezoelectric element array boards. The poling process connects the lines of all thin-film transistor arrays on the mother board together and grounds them.

As described above, a piezoelectric element is connected to a thin-film transistor array. To apply a high voltage to the piezoelectric material layer 165, conditions not to damage the thin-film transistors in the thin-film transistor array are required.

To detect and read a signal from a piezoelectric element, it is desirable that the off-current (leakage current) of the thin-film transistors in the pixel circuit be low. However, low off-current of thin-film transistors leads to application of higher voltage to the thin-film transistors in the poling process; the thin-film transistors will be broken with high probability.

The poling process in an embodiment of this specification applies a high voltage to the piezoelectric material layer in the state (condition) where the thin-film transistors generate higher off-current. This configuration significantly decreases the possibility of breakage of the thin-film transistors in the poling process. The off-current of thin-film transistors can be increased by heating the thin-film transistors or irradiating the thin-film transistors with light.

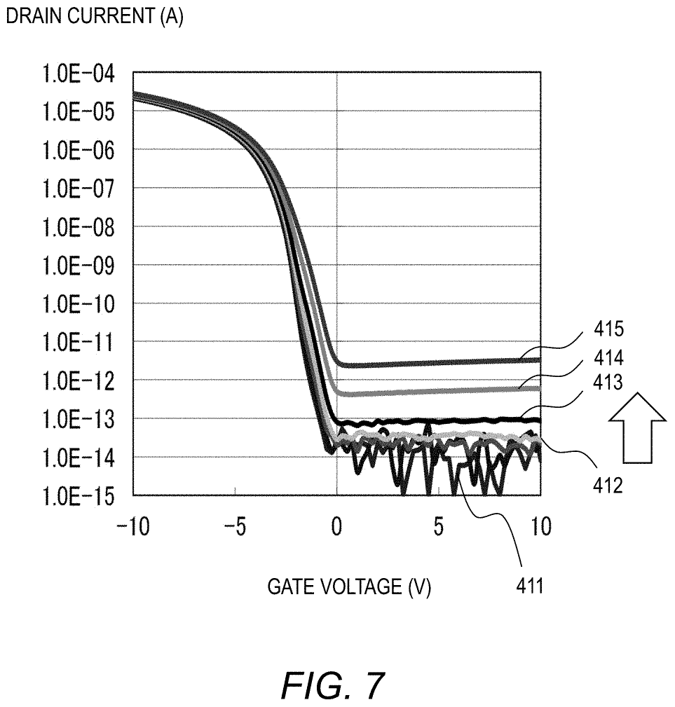

Heating a thin-film transistor to a temperature higher than the room temperature increases its off-current, which decreases the possibility of breakage caused by application of high voltage in the poling process. FIG. 7 illustrates relations between the gate voltage and the drain current of a p-channel type of thin-film transistor at different temperatures. The horizontal axis represents the gate voltage and the vertical axis represents the drain current. The drain current of a p-channel type of thin-film transistor increases with decrease of the gate voltage. The drain current when the gate voltage is higher than 0 corresponds to off-current.

In the graph of FIG. 7, some lines representing relations at different temperatures are provided with reference signs for convenience of description. The line 411 represents the relation between the gate voltage and the drain current at the temperature of −40° C. The line 412 represents the relation between the gate voltage and the drain current at the temperature of 0° C. The line 413 represents the relation between the gate voltage and the drain current at the temperature of 20° C. The line 414 represents the relation between the gate voltage and the drain current at the temperature of 50° C. The line 415 represents the relation between the gate voltage and the drain current at the temperature of 80° C. As indicated in FIG. 7, the off-current increases with increase of the temperature of the thin-film transistor.

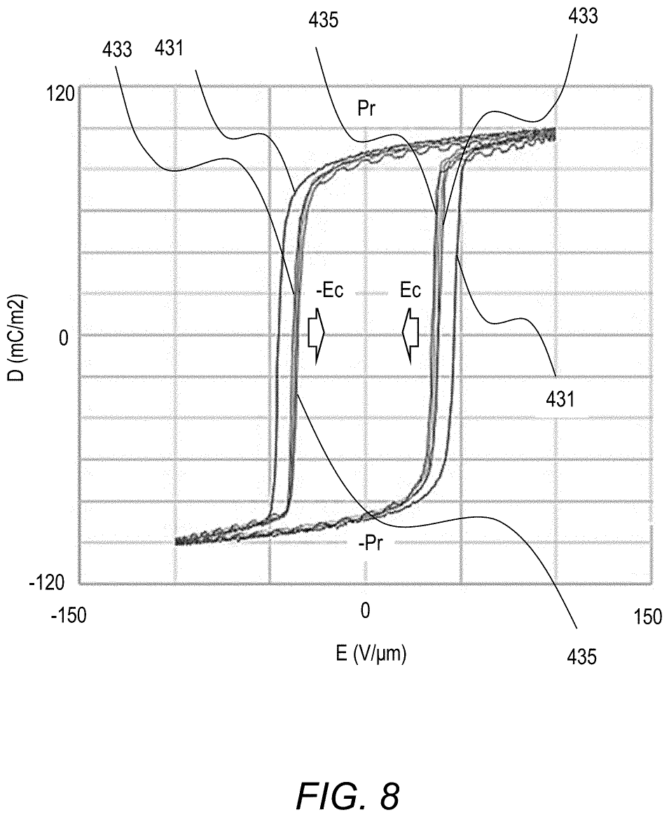

Furthermore, increased temperature lowers the voltage (electric field) required for poling the piezoelectric material. The molecules of the piezoelectric material can move easily with rise of temperature and therefore, the voltage (electric field) required for poling is lowered. FIG. 8 provides measured hysteresis loops (D-E hysteresis loops) representing relations between the electric field E applied to a piezoelectric element at different temperatures and the charge density D. The piezoelectric material used in the measurement was PVDF. Other materials exhibit similar variations. FIG. 8 provides D-E hysteresis loops at the temperatures of room temperature, 60° C., 70° C., 80° C., 90° C., and 100° C.

In FIG. 8, some of the D-E hysteresis loops at different temperatures are provided with reference signs for convenience of description. The loop 431 represents the D-E hysteresis loop at a room temperature. The loop 433 represents the D-E hysteresis loop at the temperature of 60° C. The loop 435 represents the D-E hysteresis loop at the temperature of 100° C.

The electric field to start poling (the electric field to reverse the polarization) called coercive electric field Ec is a positive external electric field at which the charge density D is 0 in a D-E hysteresis loop. The remanent polarization Pr indicating piezoelectric performance after poling can be expressed by the charge density when the external electric field is 0 in the D-E hysteresis loop. As indicated in FIG. 8, the absolute value of the coercive electric field Ec decreases with rise of temperature. Especially, the coercive electric field Ec reduces largely from the room temperature to 60° C., whereas the variation in coercive electric field Ec is small from 60° C. to 100° C.

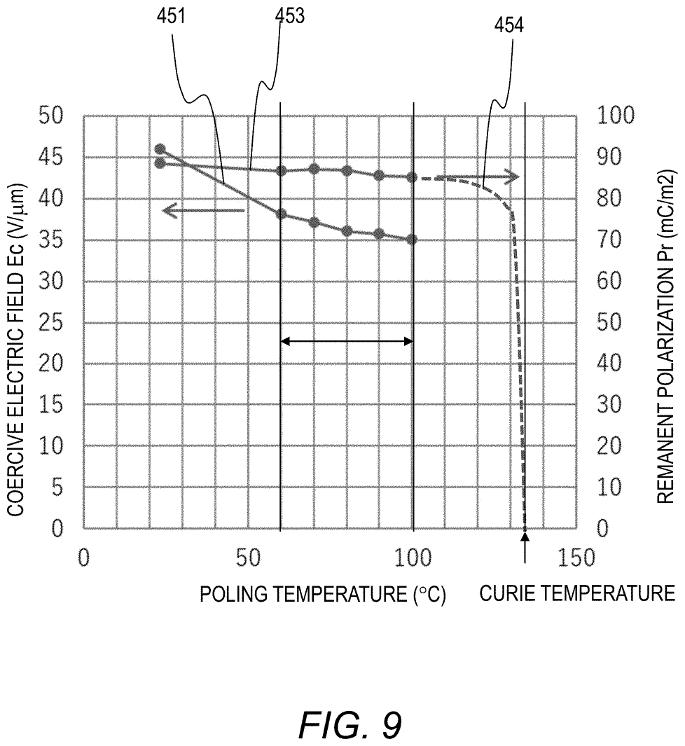

FIG. 9 illustrates the relation between the coercive electric field Ec and the temperature and the relation between the remanent polarization Pr and the temperature of a piezoelectric element acquired from the measurement results provided in FIG. 8. The horizontal axis represents the temperature; the left vertical axis represents the coercive electric field Ec; and the right vertical axis represents the remanent polarization Pr. The solid line 451 represents measured coercive electric field Ec varying with temperature. The solid line 453 represents measured remanent polarization Pr varying with temperature. The dashed line 454 represents the theoretical remanent polarization Pr varying with temperature. The remanent polarization Pr decreases significantly as the temperature approaches Curie temperature and becomes 0 at Curie temperature.

As understood from the description provided with reference to FIGS. 7 to 9, a poling process at high temperature is advantageous to increase the off-current of thin-film transistors and further, to help piezoelectric material polarize. However, for the piezoelectric material to keep appropriate remanent polarization, the poling process needs to be performed at temperature lower than a specific value.

The above-described Inventors' research revealed that poling piezoelectric elements and saving thin-film transistors from breakage can be both attained optimally when the temperature of the board is within a range from 60° C. to 100° C. (not less than 60° C. and not more than 100° C.). Accordingly, an embodiment of this specification performs the poling process for the piezoelectric material layer under the condition where the temperature of the substrate is within the range from 60° C. to 100° C. Such a poling process within the desired temperature range is available in a heating chamber, for example. Furthermore, from the standpoints of saving the thin-film transistors from breakage and having a process margin, the poling process for the piezoelectric material layer can be performed within a temperature range from 70° C. to 90° C. (not less than 70° C. and not more than 90° C.).

The step of poling S14 can employ non-contact poling utilizing plasma discharge to apply high voltage to the piezoelectric material layer. This process electrifies the piezoelectric element array board by corona discharge to apply an electric field, instead of directly applying a high voltage to the upper electrode. This process is advantageous in productivity because connecting to a voltage source for applying a high voltage is unnecessary, although the lines of the thin-film transistor array are preferably grounded for this process, too. This non-contact poling with plasma discharge is usually performed after forming a PVDF film but before forming an upper electrode.

As mentioned above, there is another way to increase the leakage current of thin-film transistors, which is irradiating the thin-film transistors with light, instead of heating. The poling process in an embodiment of this specification is performed in the state where the thin-film transistors in the piezoelectric element array are being irradiated with light. As a result, the off-current of the thin-film transistors increases and the possibility of breakage of the thin-film transistors in the poling process decreases.

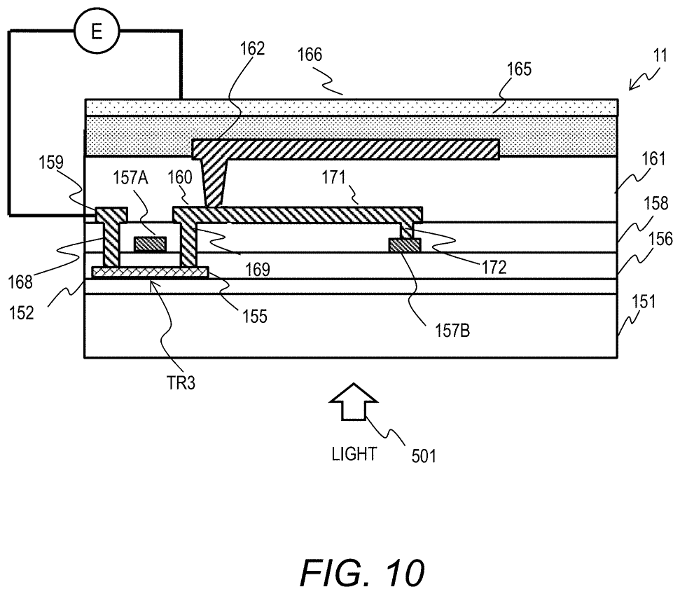

FIG. 10 schematically illustrates the poling process while irradiating the piezoelectric element array board with light. The poling process irradiates the piezoelectric element array board with light 501 from behind the insulating substrate 151. Although any wavelength of light that can increase the off-current of the thin-film transistors can be used, light in a wavelength range from green to blue can be employed. The insulating substrate 151 transmits the incoming light. Irradiating the piezoelectric element array board from behind the insulating substrate 151 allows material appropriate for the piezoelectric elements to be selected for the upper electrode 166.

The step S14 of poling the piezoelectric material layer can perform heating and illuminating together. That is to say, the poling process supplies a voltage for the poling process to the piezoelectric element array board in the state where the piezoelectric element array board is being heated and the thin-film transistors are irradiated with light. This configuration more effectively prevents breakage of the thin-film transistors. In addition, this configuration allows the light intensity or the temperature to be lowered.

The thin-film transistors in the pixel circuits for piezoelectric elements are demanded to have high off-current during the poling process. According to the Inventors' research, thin-film transistors having a specific characteristic can significantly reduce the possibility of breakage in the poling process.

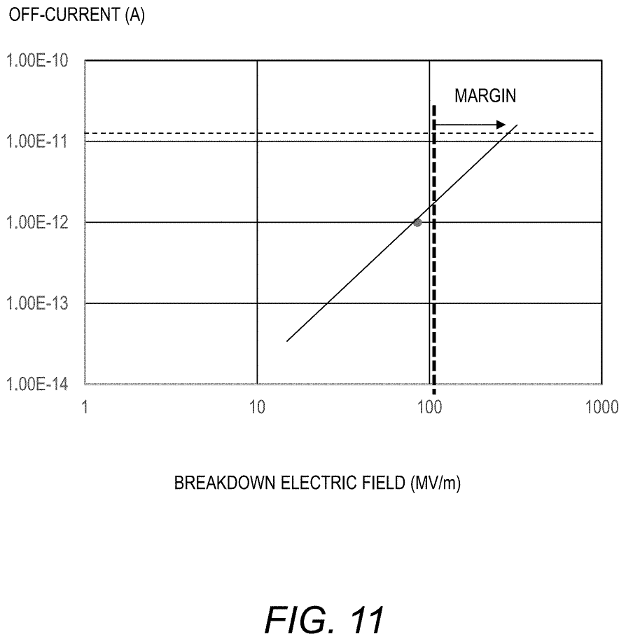

FIG. 11 illustrates a relation between the off-current of a thin-film transistor in a piezoelectric element array board and the breakdown electric field for the thin-film transistor. As indicated by the solid line representing the experimental result, when the off-current is high, the breakdown electric field is also high. The breakdown electric field can be considered as the electric field to be applied to the piezoelectric elements. Appropriate poling of piezoelectric elements requires an electric field not less than 100 MV/m. Considering the manufacture margin, off-current higher than 2.5E-11 A can effectively prevent breakage of thin-film transistors. Under a normal operating temperature (room temperature: for example, 25° C.), thin-film transistors have off-current not more than 1.0E-12 A.

The voltage applied to the thin-film transistors in the circuit diagram of FIG. 2 is the voltage at the node N1. The voltage at the node N1 depends on the charge generated by the piezoelectric element PE and the leakage current of the thin-film transistors. If the piezoelectric element (the lower electrode thereof) has a smaller area, the amount of the generated charge is smaller, reducing the off-current demanded for the thin-film transistors.

The following relation is obtained from the area of the piezoelectric element providing the data in FIG. 11 and the foregoing values of off-current. The voltage at the node N1 is determined by the relative ratio of the amount of charge decreased by the leakage current of the thin-film transistors to the amount of charge stored in the capacitor of the PVDF because of the applied voltage in the poling process. The capacitance of the PVDF is proportional to the area of the pixel; the voltage is determined when the ratio of the leakage current of the thin-film transistors to the area takes a specific value. The inventors calculated the coefficients from the experimental results and obtained the following relation:

Ioff@80° C.≥0.01×S,

where Ioff@80° C. represents the off-current at 80° C. and S represents the area of the piezoelectric element (the lower electrode or the pixel electrode thereof). The unit of the off-current is A and the unit of the area is m².

In the case where the poling process is performed in a temperature range from 60° C. to 100° C. as described in the section of the method of manufacturing a piezoelectric element array board, thin-film transistors having the above-described characteristics generate off-current sufficient to avoid breakage. Thin-film transistors that generate off-current not less than (0.01×S) A or 2.5E-11 A can avoid breakage more reliably.

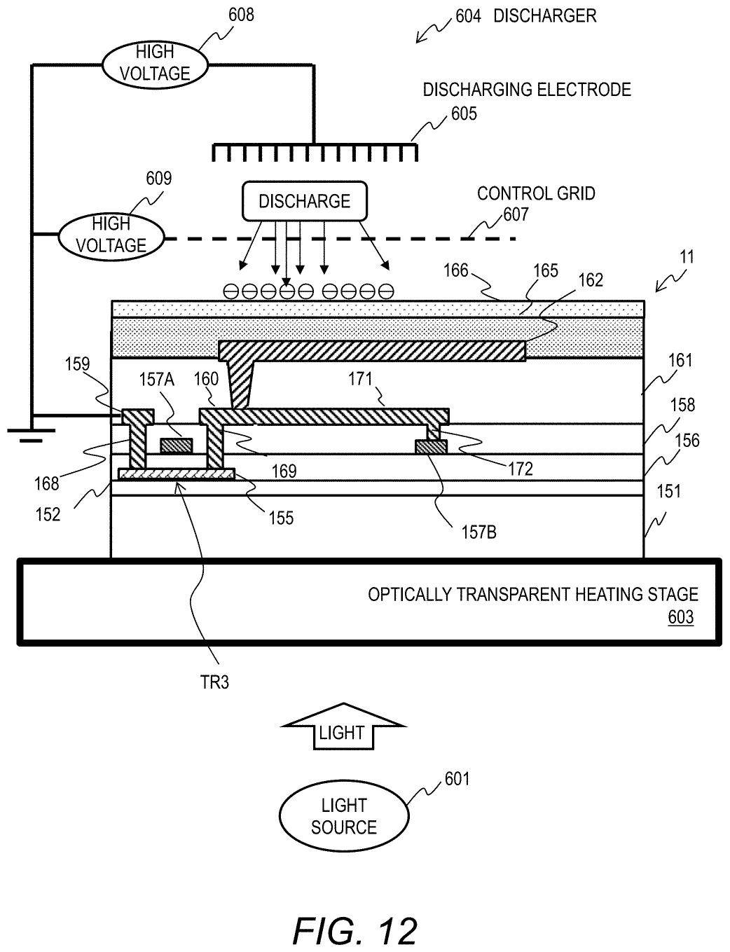

FIG. 12 schematically illustrates a configuration example of an apparatus for poling a piezoelectric material layer while irradiating the piezoelectric element array board with light. The poling apparatus includes a light source 601, an optically transparent heating stage 603, and a discharger 604. The discharger 604 includes a discharging electrode 605 connected to a high-voltage source 608 and a control grid 607 connected to a high-voltage source 609. The poling apparatus illustrated in FIG. 12 performs non-contact poling utilizing plasma discharge. This method electrifies the piezoelectric element array board by corona discharge to apply an electric field, instead of directly applying a high voltage to the upper electrode. This method is advantageous in productivity because each device does not need to be connected to an electrode.

The piezoelectric element array board 11 is placed on the optically transparent heating stage 603 with the insulating substrate 151 facing down. In the example of FIG. 12, the terminals of the piezoelectric element array board 11 are grounded. The optically transparent heating stage 603 heats the piezoelectric element array board 11. In other words, the optically transparent heating stage 603 functions as a heating device for heating the piezoelectric element array board 11. The optically transparent heating stage 603 can include a heater or can be heated with infrared light before start of the poling process, for example. Instead of the stage, the chamber can be heated with a heating device.

The poling apparatus irradiates the piezoelectric element array board 11 with light from the light source 601 through the optically transparent heating stage 603. The light source 601 is disposed underneath the optically transparent heating stage 603. The light source 601 does not need to be located underneath the optically transparent heating stage 603, but it should be disposed so that the region to be exposed to plasma discharge will be irradiated with light. The poling apparatus can include an optical system (light source system) configured to irradiate the underside of the optically transparent heating stage 603 with light from the light source 601.

The optically transparent heating stage 603 transmits light from the light source 601. The light emitted from the light source 601 can be light in a wavelength range from 300 nm to 600 nm, which can be transmitted through the glass substrate and the transparent stage and easily absorbed by the semiconductor active layer. The poling apparatus performs plasma discharge while heating the piezoelectric element array board 11 with the optically transparent heating stage 603 and irradiating the thin-film transistors with light from the light source 601.

Discharge occurs between the discharging electrode 605 and the piezoelectric element array board 11 so that the surface of the piezoelectric element array board 11 is charged with minus ions (charges). As a result, an electric field is applied to the piezoelectric material. The control grid 607 can control the charge distribution optimally.

As described above, the plasma poling apparatus includes an optically transparent stage with a heating function for supporting the insulating substrate with piezoelectric material thin films and switching elements fabricated thereon and irradiates the piezoelectric element array board with light from behind the optically transparent stage. The plasma poling apparatus applies an electric field generated by plasma discharge to the piezoelectric element array board in a state where the piezoelectric element array board is heated and being irradiated with light. Through this operation, the piezoelectric material polarizes.

As set forth above, embodiments of this disclosure have been described; however, this disclosure is not limited to the foregoing embodiments. Those skilled in the art can easily modify, add, or convert each element in the foregoing embodiments within the scope of this disclosure. A part of the configuration of one embodiment can be replaced with a configuration of another embodiment or a configuration of an embodiment can be incorporated into a configuration of another embodiment.

What is claimed is:

1. A method of manufacturing a piezoelectric element array board, comprising:
fabricating a plurality of piezoelectric element control circuits including one or more thin-film transistors on a substrate;
fabricating a plurality of piezoelectric elements on the substrate; and
poling a piezoelectric material by applying an electric field to a piezoelectric material layer of the plurality of piezoelectric elements while maintaining the one or more thin-film transistors in a state of generating higher leakage current, after fabricating the plurality of piezoelectric elements and the plurality of piezoelectric element control circuits.

2. The method according to claim 1, wherein the maintaining the one or more thin-film transistors in a state of generating higher leakage current includes heating the piezoelectric element array board.

3. The method according to claim 2, wherein the maintaining the one or more thin-film transistors in a state of generating higher leakage current includes maintaining the piezoelectric element array board in a state of not less than 60° C. and not more than 100° C.

4. The method according to claim 3, wherein the maintaining the one or more thin-film transistors in a state of generating higher leakage current includes maintaining the piezoelectric element array board in a state of not less than 70° C. and not more than 90° C.

5. The method according to claim 1, wherein the maintaining the one or more thin-film transistors in a state of generating higher leakage current includes irradiating the one or more thin-film transistors with light.

6. The method according to claim 5, wherein the maintaining the one or more thin-film transistors in a state of generating higher leakage current includes irradiating the one or more thin-film transistor with light from behind the substrate.

7. The method according to claim 1, wherein the maintaining the one or more thin-film transistors in a state of generating higher leakage current includes heating the piezoelectric element array board while irradiating the one or more thin-film transistors with light.

8. The method according to claim 1, wherein the higher leakage current is equal to or higher than a value obtained by multiplying an area of a piezoelectric element by 0.1 A.

9. A piezoelectric element array board, comprising:
a substrate;
a piezoelectric element array including a plurality of piezoelectric elements on the substrate; and
a thin-film transistor array on the substrate, the thin-film transistor array being configured to control the plurality of piezoelectric elements,
wherein the thin-film transistor array includes a plurality of piezoelectric element control circuits each configured to control one of the plurality of piezoelectric elements, and
wherein leakage current of each of the one or more thin-film transistors at 80° C. is equal to or higher than a value obtained by multiplying an area of a piezoelectric element by 0.1 A.

10. The piezoelectric element array board according to claim 9, wherein leakage current of each of the one or more thin-film transistors at 80° C. is equal to or higher than 2.5E-11 A.

11. A poling apparatus configured to pole a piezoelectric material in a piezoelectric element array board,
the piezoelectric element array board including an insulating substrate, a plurality of piezoelectric element control circuits including one or more thin-film transistors on the insulating substrate, and a plurality of piezoelectric elements including a piezoelectric material layer on the insulating substrate,
the poling apparatus comprising:
a plasma discharging device;
an optically transparent stage configured to hold the piezoelectric element array board placed in such a manner that the insulating substrate is on the optically transparent stage;
a heating device configured to heat the piezoelectric element array board; and
a light source system configured to irradiate the piezoelectric element array board with light from behind the optically transparent stage,
wherein the plasma discharging device is configured to pole the piezoelectric material layer of the plurality of piezoelectric elements by electrifying the piezoelectric element array board in a state where the piezoelectric element array board is heated and being irradiated with light.
